(19) United States
(12) Patent Application Publication
(10) Pub. No.: US 2026/0349013 A1
(43) Pub. Date: Nov. 5, 2026

(54) PRIMARY-SIDE CURRENT SENSING UNIT APPLIED TO A TRANSFORMER-BASED POWER CONVERTER

(71) Applicant: MetaPWR Electronics Co., Ltd., Shanghai (CN)

(72) Inventors: Da Jin, Shanghai (CN); Zhengyu YE, Shanghai (CN); Yahong Xiong, Shanghai (CN)

(73) Assignee: MetaPWR Electronics Co., Ltd., Shanghai (CN)

(21) Appl. No.: 19/658,711

(22) Filed: Apr. 27, 2026

(30) Foreign Application Priority Data
May 3, 2025 (CN) 202510569532.5

(51) Int. Cl. G01R 19/00; H02M 1/00; H02M 3/335

(52) U.S. Cl. CPC G01R 19/0046; H02M 1/0009; H02M 3/33571

(57) ABSTRACT

The present application provides a primary-side current sensing unit applied to a transformer-based power converter; the primary-side current sensing unit is implemented by selecting a full-bridge circuit as the primary-side circuit and combining it with a current sensing unit located in the primary-side of the transformer. The current information during the conduction time of the primary-side switches is detected through a current sampling unit. On the other hand, a prediction unit is added to the current sensing unit to predict the current information during the turn-off time of the primary-side switches.

### CROSS-REFERENCE TO RELATED APPLICATION

This application claims the priority benefit of Chinese patent application CN202510569532.5 filed on May 3, 2025. The entirety of the above-mentioned patent application is hereby incorporated by reference herein and made a part of this specification.

### BACKGROUND

In recent years, with the technological development in fields such as data centers, artificial intelligence, and supercomputers, an increasing number of powerful ASICs have been put into use, such as CPUs, GPUs, machine learning accelerators, network switches, and servers, which consume large amounts of current, for example, up to thousands of amperes. To meet the requirement for fast response to load transients, the current industry practice is to adopt a two-stage converter, in which the first-stage converter is a ratio converter, for example, converting a 48 V voltage into a 6 V voltage as shown in FIG. 1A, together with a second-stage converter, for example, usually implemented by paralleling multiple buck phases, so as to achieve voltage conversion from 48 V to 1 V or 0.8 V. However, due to the presence of the low-voltage bus, 6 V, relatively large conduction losses are generated, the overall system efficiency is low, and the application is relatively complicated.

A second approach adopts a single-stage power converter, eliminating the low-voltage bus and directly converting 48 V to 1 V or lower. The single-stage converter has relatively high conversion efficiency and high power density. However, a converter for supplying power to an XPU needs to detect output inductor current information accurately and in real time. In the prior art, a topology of the single-stage power converter usually adopts a transformer-based topology to realize voltage step-down and voltage regulation functions; the primary-side circuit adopts a half-bridge circuit, and the secondary-side circuit adopts a center-tapped rectifier circuit or a current-doubler rectifier circuit, and the like. In order to detect the current flowing through the inductor in the secondary-side circuit, it is usually implemented by detecting the current during the conduction period of the secondary-side MOSFET, as shown by the current sensing unit Ucs in FIG. 1B. However, because the secondary-side current is relatively large, and the number of MOSFETs connected in parallel on the secondary-side is relatively large, the current sensing unit becomes excessively complicated and bulky. The present invention provides a current sensing unit, which, by selecting a full-bridge circuit as the primary-side circuit and combining it with a current sensing unit located in the primary-side of the transformer, can solve the above problems.

### SUMMARY

In view of the above, one of the objectives of the application is to provide a primary-side current sensing unit applied to a transformer-based power converter, wherein the power converter comprises a primary-side circuit, a secondary-side circuit, an input positive terminal, an input negative terminal, an output positive terminal, and an output negative terminal;

The primary-side circuit is connected across the input positive terminal and the input negative terminal, and the primary-side circuit comprises a primary-side switch;

The secondary-side circuit is connected across the output positive terminal and the output negative terminal, and the secondary-side circuit comprises an inductor;

The primary-side current sensing unit comprising: a current sampling unit connected between the primary-side circuit and the input negative terminal;

A sample-and-hold unit comprising a sampling switch and a filter unit, wherein an on-time of the sampling switch is less than or equal to an on-time of the primary-side circuit; and

A variable-gain amplification unit receiving an output voltage of the sample-and-hold unit and outputting a current sensing signal after amplifying the output voltage by a corresponding gain; wherein the gain of the variable-gain amplification unit is adjustable; wherein the output voltage of the sample-and-hold unit comprises current information during the on-time of the primary-side circuit.

Preferably, further comprising a prediction unit; the prediction unit receives the output voltage of the sample-and-hold unit, and an output voltage of the prediction unit serves as an input of the variable-gain amplification unit, and the prediction unit is configured to predict current information during an off-time of the primary-side circuit.

Preferably, the prediction unit predicts the current information during the off-time of the primary-side circuit according to an output voltage of the secondary-side circuit and an inductance value, or predicts the current information according to a slope of a rising stage of the output voltage of the sample-and-hold unit and the output voltage of the secondary-side circuit.

Preferably, the output voltage of the sample-and-hold unit is superimposed with a DC component and then input to the prediction unit.

Preferably, the sample-and-hold unit adopts a hybrid DC and AC sensing mode.

Preferably, the prediction unit comprises an error detection unit; the error detection unit adjusts a slope of a falling stage of the current sensing signal according to an error signal of the current sensing signal; the error signal is a difference between a terminal value of the falling stage and an initial value of a rising stage in the current sensing signal.

Preferably, the prediction unit further comprises a power supply terminal, a ground terminal, a first adjustable current source, a second adjustable current source, a first switch, a second switch, a third switch, and a holding capacitor; an on-time of the first switch is consistent with an on-time of the sampling switch; an on-interval of the second switch is complementary to an on-interval of the first switch; and an on-time of the third switch is shorter than the on-time of the first switch.

Preferably, one end of the first switch is electrically connected to an output terminal of the first adjustable current source, and another end of the first switch is electrically connected to one end of the second switch, one end of the third switch and one end of the holding capacitor, and serves as an output terminal of the prediction unit; an input terminal of the first adjustable current source is electrically connected to the power supply terminal; another end of the third switch is electrically connected to the sample-and-hold unit; another end of the second switch is electrically connected to an input terminal of the second adjustable current source; an output terminal of the second adjustable current source and another end of the holding capacitor are both grounded; and another input terminal of the second adjustable current source is electrically connected to the error detection unit.

Preferably, when the third switch is turned on, the output voltage of the prediction unit is equal to the output voltage of the sample-and-hold unit.

Preferably, the sample-and-hold unit adopts a DC sensing mode.

Preferably, the sampling switch is turned on with a delay relative to turn-on of the primary-side switch.

Preferably, the filter unit comprises a filter resistor and a filter capacitor.

Preferably, the filter capacitor is a parasitic capacitor within the primary-side current sensing unit.

Preferably, the current sampling unit comprises a sampling resistor, and during a conduction period of the sampling switch, a voltage across the filter capacitor falls or rises following a voltage across the sampling resistor; a falling or rising slope of the voltage across the filter capacitor depends on a waveform of the voltage across the sampling resistor and a time constant of the filter resistor and the filter capacitor.

Preferably, the sampling switch is turned on during an interval in which the primary-side circuit is turned on, and an on-off frequency of the sampling switch is consistent with a frequency of a current waveform of the inductor.

Preferably, energy is transferred between the primary-side circuit and the secondary-side circuit through transformer coupling.

Preferably, the input negative terminal is short-circuited to the output negative terminal.

Preferably, further comprising a controller, wherein the current sensing signal serves as an input signal of the controller, and together with other control signals, generates a pulse-width control signal.

Preferably, current monitoring and reporting are performed through the current sensing signal.

Preferably, the monitoring and reporting are performed between a communication bus of the controller and an XPU voltage management unit.

Preferably, the current sensing signal participates in droop control, current sharing control, current protection, or current-mode COT control required by the converter.

Preferably, the primary-side circuit is a full-bridge circuit, and the full-bridge circuit comprises two switch bridge arms electrically connected in parallel, each of the switch bridge arms comprises an upper switch and a lower switch electrically connected in series.

Preferably, the current sampling unit comprises a sampling resistor, and the sampling resistor is connected in series between sources of the two lower switches connected in parallel and the input negative terminal.

Preferably, the sampling switch is synchronously turned on or off with either one of the two primary-side lower switches.

Preferably, the current sampling unit comprises current mirror circuits integrated in the two primary-side lower switches, and the current sensing signal is a superposition of conduction currents of the two lower switches.

Compared with the prior art, the application has the following beneficial effects:
(1) The present invention provides a primary-side current sensing unit applied to a transformer-based power converter; the primary-side current sensing unit is implemented by selecting a full-bridge circuit as the primary-side circuit and combining it with a current sensing unit located in the primary-side of the transformer. The current information during the conduction time of the primary-side full-bridge switches is detected through a current sampling unit; the primary-side current sensing unit has a simple circuit structure, and the detected current signal has good real-time performance, low distortion, and high accuracy.
(2) The present invention further improves the accuracy of the current sensing signal by adding a prediction unit to the current sensing unit to predict the current information during the turn-off time of the primary-side switches.

### BRIEF DESCRIPTION OF THE DRAWINGS

FIGS. 1A-1C show the prior art;

FIGS. 2A and 2B show the application of the primary-side current sensing method in a half-bridge circuit;

FIGS. 3A and 3B show the application of the primary-side current sensing method in a full-bridge circuit;

FIGS. 4A and 4B show one embodiment of the primary-side current sensing unit;

FIGS. 5A and 5B show another embodiment of the primary-side current sensing unit;

FIGS. 6A and 6D show another embodiment of the primary-side current sensing unit;

FIG. 7 is a schematic wiring diagram showing the connection between multi-phase primary-side current sensing signals and a multi-phase controller in a parallel application of multi-phase transformer-based full-bridge power converters.

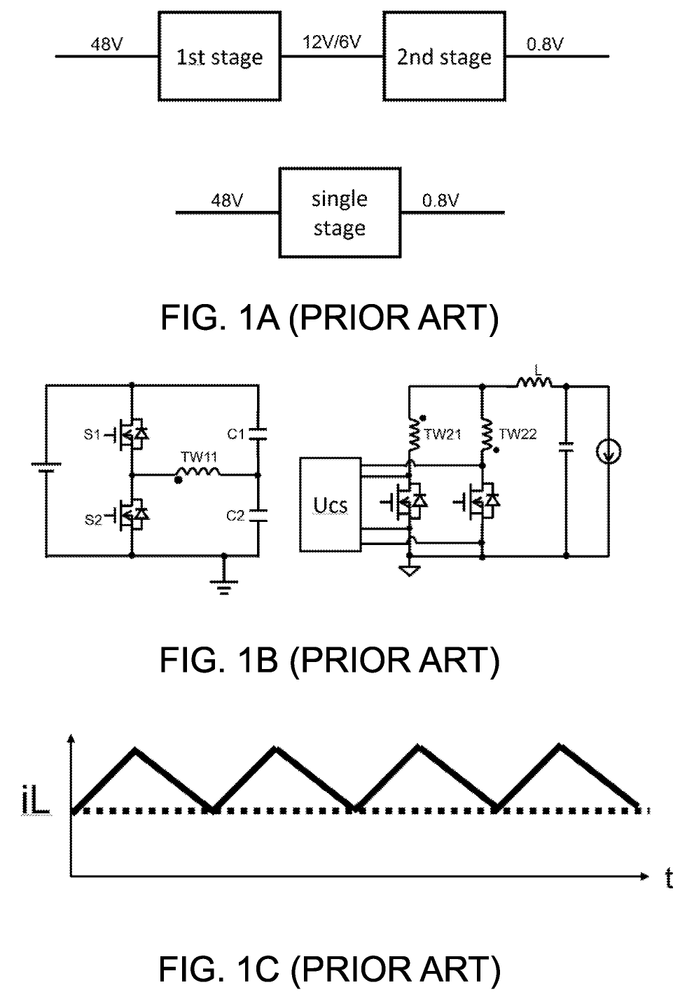

### DESCRIPTION OF THE EMBODIMENTS

One of the cores of the present application is to provide a primary-side current sensing unit applied to a transformer-based power converter.

Technical solutions in the embodiments of the present disclosure will be clearly and completely described below with reference to the accompanying drawings in the embodiments of the present disclosure. Apparently, the described embodiments are merely some rather than all of the embodiments of the present disclosure. All other embodiments obtained by a person of ordinary skill in the art based on the embodiments of the present disclosure without creative efforts shall fall within the protection scope of the present disclosure.

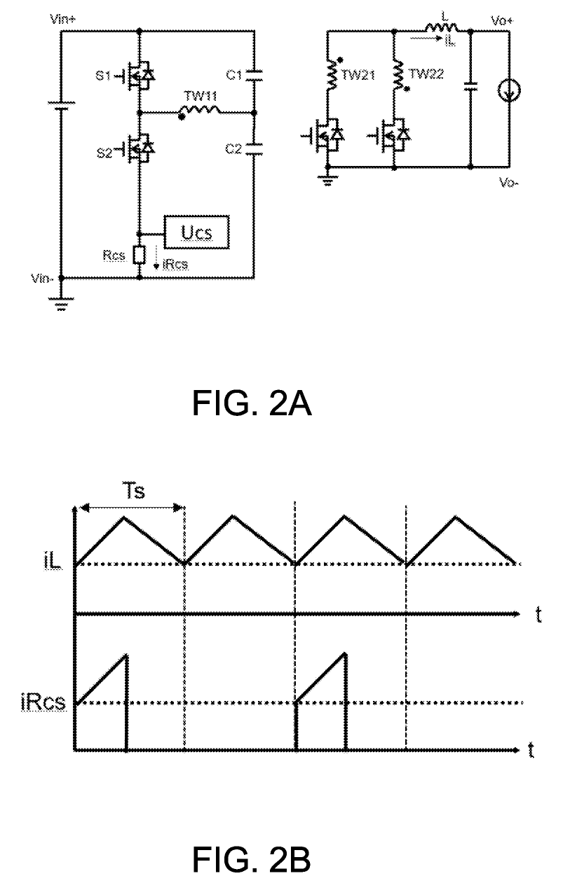

The present invention provides a primary-side current sensing method and implementation for a transformer-based power converter; FIGS. 2A and 2B show the application of the primary-side current sensing method in a half-bridge circuit; the power converter includes a primary-side circuit and a secondary-side circuit; the primary-side circuit is a half-bridge circuit, and the secondary-side circuit is a center-tapped rectifier circuit; a primary winding TW11 and secondary windings TW21 and TW22 are coupled on one magnetic core to form a transformer. The primary-side circuit includes the half-bridge circuit, an input positive terminal Vin+, and an input negative terminal Vin-; the secondary-side circuit includes the center-tapped rectifier circuit, an output positive terminal Vo+, and an output negative terminal Vo-; the primary-side circuit and the secondary-side circuit may be isolated or non-isolated. In this embodiment, the case where the primary-side circuit and the secondary-side circuit are non-isolated, that is, the input negative terminal Vin- is short-circuited to the output negative terminal Vo-, is taken as an example for description. The turns ratio of the primary winding TW11 to the secondary winding TW21 or TW22 is 2N:1. A current sensing unit includes a sampling resistor Rcs and a sampling unit Ucs; the sampling resistor Rcs is connected in series between a source of a lower switch S2 and the input negative terminal Vin-; that is, in a half-bridge arm, an upper switch S1, the lower switch S2, and the sampling resistor Rcs are sequentially connected in series and then connected across the input positive terminal Vin+ and the input negative terminal Vin-; in a capacitor bridge arm, an upper capacitor C1 and a lower capacitor C2 connected in series is electrically connected, and then connected across the input positive terminal Vin+ and the input negative terminal Vin-; in the connection between the current sensing unit and the half-bridge circuit, a current iRcs flowing through the sampling resistor Rcs has a waveform consistent with a current flowing through the lower switch S2, and the waveform frequency of the current iRcs through the sampling resistor Rcs is half that of the waveform frequency of a current iL through an output inductor L, with its current waveform shown in FIG. 2B. FIG. 2B includes the output inductor current waveform iL and the current waveform iRcs flowing through the sampling resistor Rcs. During the conduction period of the lower switch S2, the amplitude of the current iRcs flowing through the sampling resistor Rcs is 1/2N of the amplitude of the current iL flowing through the output inductor L; at other times, the current flowing through the sampling resistor Rcs is 0. This sampling circuit has a simple structure, but its sampling speed is relatively slow and cannot quickly respond to changes in the current iL of the output inductor L, because the sampling resistor Rcs can only detect the current when the lower switch S2 is on, and cannot simultaneously detect the current when the upper switch S1 is on, resulting in poor real-time current sensing, high current distortion, and poor current accuracy.

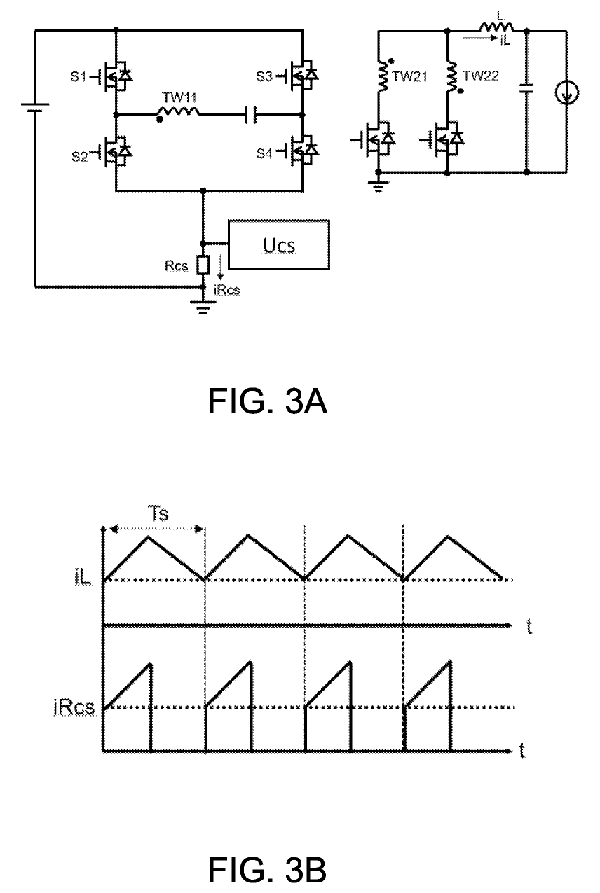

To solve the above problem, the present invention further improves a primary-side current sensing method applied to a transformer-based power converter; the primary-side current sensing method is implemented by selecting a full-bridge circuit as the primary-side circuit and combining it with a current sensing unit located on the primary side, as specifically shown in FIGS. 3A and 3B. Compared with the connection manner shown in FIG. 2A, the difference in FIG. 3A is that the primary-side circuit is changed from the half-bridge circuit to the full-bridge circuit, and the turns ratio of the primary winding TW11 to the secondary winding TW21 or TW22 is N:1; the position of the sampling resistor Rcs is changed from being connected in series between the source of the lower switch S2 and the input negative terminal Vin- to being connected in series between the full-bridge circuit and the input negative terminal Vin-, that is, in series between the sources of the lower switches S2 and S4 connected and the input negative terminal Vin-. The advantage of this arrangement is that the current flowing through the sampling resistor Rcs is the superposition of the current of the lower switch S2 and the current of the lower switch S4, and the waveform frequency of the current through the sampling resistor Rcs is consistent with the waveform frequency of the current through the output inductor L, with its current waveform shown in FIG. 3B. FIG. 3B shows the waveform of the current iL of the output inductor and the waveform of the current iRcs flowing through the sampling resistor Rcs. During the conduction period of the lower switch S2, an amplitude of the current iRcs flowing through the sampling resistor Rcs is 1/N of the amplitude of the current iL flowing through the output inductor L; during the conduction period of the lower switch S4, the amplitude of the current iRcs flowing through the sampling resistor Rcs is 1/N of the amplitude of the current iL flowing through the output inductor L; at other times, the current iRcs flowing through the sampling resistor Rcs is 0. In the circuit shown in FIG. 3A, the connection manner of the sampling resistor Rcs with the full-bridge circuit enables the sampling resistor Rcs to detect the current waveforms during the conduction periods of both lower switches S2 and S4 on the primary side, thereby enabling the sampling circuit to have the characteristics of fast current sampling speed and quick response to changes in the current of the output inductor L, with good real-time performance, low distortion, and high accuracy.

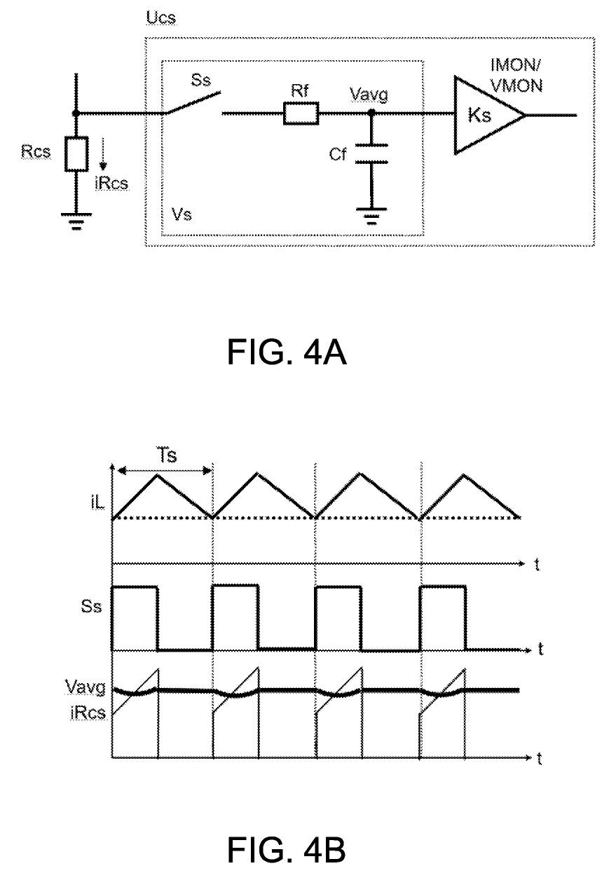

A specific implementation circuit of the sampling unit Ucs shown in FIG. 3A is shown in FIG. 4A. The sampling unit Ucs includes a sample-and-hold circuit Vs and an amplification unit Ks. Specifically, the sample-and-hold circuit Vs includes a sampling switch Ss and a filter unit RC. The sampling switch Ss is turned on when the current iRcs is greater than a threshold, for example, 0 or another value, and is turned off when the current iRcs is less than or equal to the threshold; in other implementations, the sampling switch Ss may be turned on when the primary-side lower switch S2 or S4 is on, and turned off when the primary-side lower switch S2 or S4 is off. The amplitude of the voltage signal Vavg output by the sample-and-hold circuit Vs is relatively small; after passing through the amplification unit Ks, it is converted into a large-amplitude current sensing signal IMON or voltage sensing signal VMON, collectively referred to as IMON/VMON; the sensing signal IMON/VMON is more conducive to achieving precise control of an output current of the transformer-based power converter. The filter unit RC includes a filter resistor Rf and a filter capacitor Cf, which are used to hold an input signal of the amplification unit Ks while filtering signal noise from the input signal of the amplification unit Ks. Because the converter operates at a relatively high frequency, the filter capacitor Cf may also be implemented by the parasitic capacitance of the amplification unit Ks. Compared with FIGS. 3B, 4B, additionally shows the turn-on and turn-off indication waveform of the sampling switch Ss, as well as the waveform of the voltage Vavg across the filter capacitor Cf. A high level indicates that the sampling switch Ss is on, and a low level indicates that the sampling switch Ss is off; the on&off frequency of Ss is consistent with the frequency of the waveform of the current iL through the secondary-side inductor L, and during the rising period of the current through the secondary-side inductor L, that is, corresponding to the conduction period of the primary-side lower switch S2 or S4, the sampling switch Ss is correspondingly turned on; during other periods, the sampling switch Ss is correspondingly turned off. During the conduction period of the sampling switch Ss, the voltage Vavg across the filter capacitor Cf falls or rises following the voltage across the sampling resistor Rcs; a falling slope or a rising slope of the Vavg depends on the voltage waveform across the sampling resistor Rcs and a time constant of Rf and Cf. During the turn-off period of the sampling switch Ss, the voltage Vavg remains substantially unchanged. By means of the above method, when the time constant of Rf and Cf is relatively large, Vavg approximates a DC signal, and a ratio of its voltage amplitude to the average current of the secondary-side output inductor L is constant. When the time constant of Rf and Cf is relatively small, and during the conduction period of the sampling switch Ss, the waveform of Vavg approximately coincides with the voltage waveform across the sampling resistor Rcs, that is, it is proportional to the current waveform of the secondary-side output inductor L; however, during the turn-off period of Ss, the waveform of Vavg remains substantially unchanged, that is, it is no longer proportional to the current waveform of the secondary-side output inductor L.

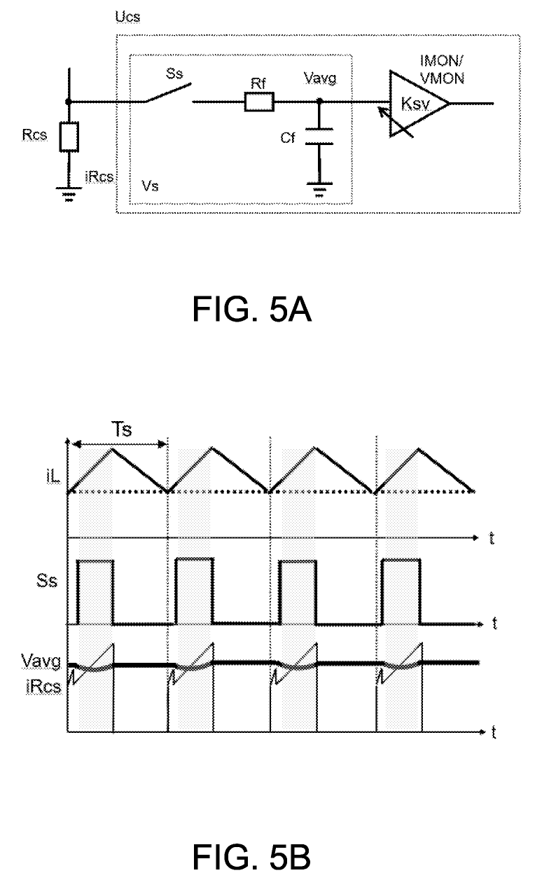

FIGS. 5A and 5B show another implementation of the sampling unit Ucs. The sampling unit Ucs includes a sample-and-hold unit Vs and a variable-gain amplification unit Ksv. The sample-and-hold circuit Vs adopts a DC sensing mode and only detects the DC component of the current iRcs when the primary side is on. Because of the junction capacitance of the primary-side switch and the reverse recovery of the body diode of the secondary-side synchronous rectifier, a spike current exists in the primary-side current iRcs at the instant when the primary-side lower switch S2 or S4 is turned on. In order to avoid the influence of the spike current on the accuracy of current sensing, the sampling switch Ss adopts delayed turn-on, that is, it is turned on after a delay from the turn-on of the primary-side switch by a period of time, the length of which is related to the time width of the spike current, as specifically shown in FIG. 5B. Compared with FIG. 4B, the difference in FIG. 5B lies in the start turn-on time of the sampling switch Ss, which is later than the start turn-on time of the primary-side lower switch S2 or S4, that is, later than the start rising time of the secondary-side inductor current; thus, the turn-on time of the sampling switch Ss is shorter than the turn-on time of the primary-side lower switch S2 or S4, thereby reducing the influence of the current spike on iRcs at the instant when the primary-side lower switch S2 or S4 is turned on on the sampling unit Ucs. In addition, in this implementation, the variable-gain amplification unit Ksv is adopted, and the gain and an offset voltage of the amplification unit Ksv are modified by means of calibration, thereby improving the accuracy of current sensing.

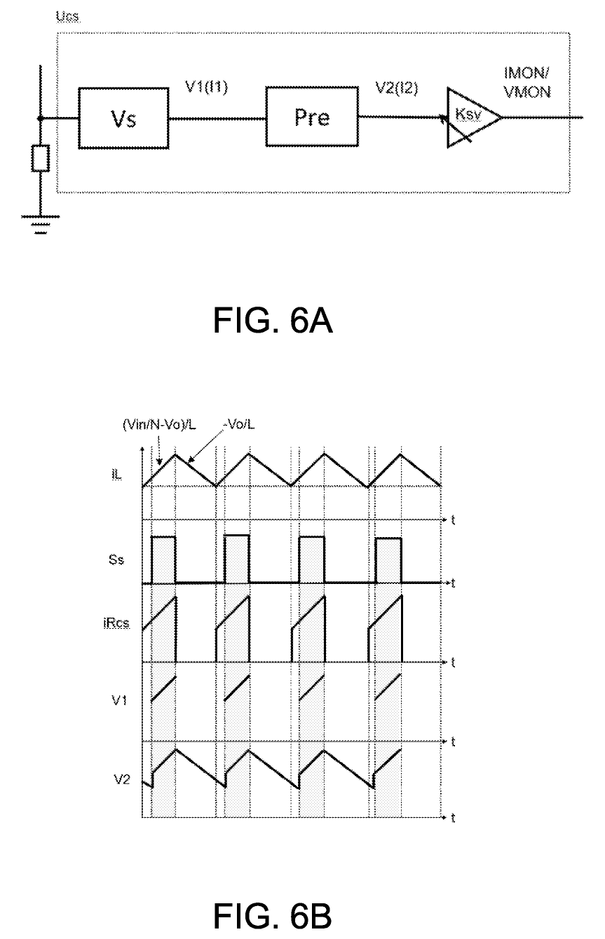

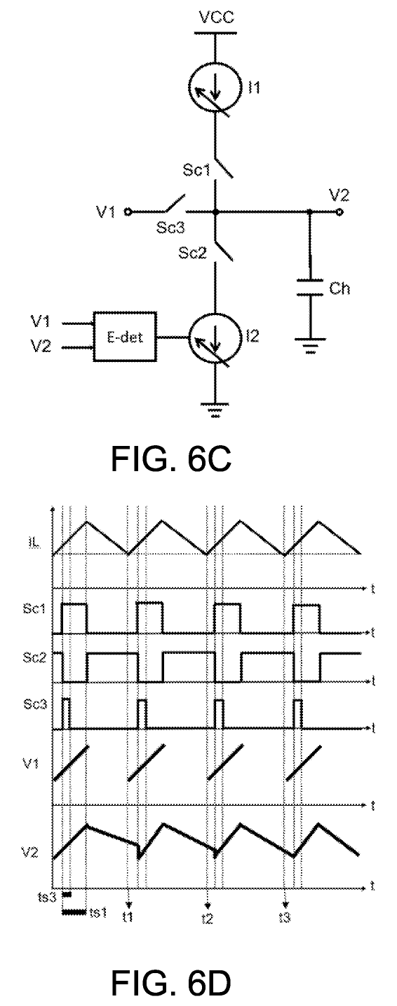

FIGS. 6A and 6B show another implementation of the sampling unit Ucs. The sampling unit Ucs includes a sample-and-hold circuit Vs, a prediction unit Pre, and a variable-gain amplification unit Ksv. The sampling unit Ucs adopts a hybrid DC and AC sensing mode, that is, an input waveform of the variable-gain amplification unit Ksv is always proportional to the current waveform of the secondary-side output inductor L, thereby obtaining a more accurate current signal. Since the minimum value of the inductor current may be negative, for the convenience of prediction by the Pre, the Vs needs to superimpose a DC component on the detected current to ensure that an output signal V1 or I1, collectively referred to as V1(I1) or V1, of Vs is always positive. Because the primary-side current iRcs only includes the current information in the rising stage of the inductor current iL, the current information in the falling stage of the inductor current iL is supplemented by prediction by the prediction unit Pre. According to the slope relationship of the inductor current, the slope of the inductor current iL in the rising stage is (Vin/N-Vo)/L, and the slope of the inductor current iL in the falling stage is -Vo/L. Therefore, according to the output voltage Vo and the inductance value, the waveform of the inductor current during the falling stage can be predicted. The inductance value may be preset in the prediction unit, or may be estimated according to the slope of the voltage V1 during its rising stage. Compared with FIGS. 5B, 6B, further shows a waveform of an output signal V1 of the sample-and-hold circuit Vs and the waveform of an output signal V2 or I2, collectively referred to as V2(I2) or V2, of the prediction unit Pre. The slope of the falling stage of the voltage V2 shown in FIG. 6B is only an example, and the falling slope may also be finely adjusted to obtain a voltage waveform V2 similar to the inductor current.

FIG. 6C shows a schematic circuit diagram of a prediction unit Pre, and the prediction unit Pre includes an automatic correction function. The prediction unit includes a power supply terminal, a ground terminal, adjustable current sources I1 and I2, switches Sc1, Sc2, and Sc3, an error detection unit E-det, and a holding capacitor Ch. One end of the switch Sc1 is electrically connected to an output terminal of the adjustable current source I1, and the other end of the switch Sc1 is electrically connected to one end of the switch Sc2, one end of the switch Sc3 is electrically connected to one end of the holding capacitor Ch, and serves as an output terminal of the prediction unit; an input terminal of the adjustable current source I1 is electrically connected to the power supply terminal; the other end of the switch Sc3 is electrically connected to the sample-and-hold unit; the other end of the switch Sc2 is electrically connected to an input terminal of the adjustable current source I2; an output terminal of the adjustable current source I2 and the other end of the holding capacitor are both grounded; and another input terminal of the adjustable current source I2 is electrically connected to the error detection unit. The control timing of the switches Sc1, Sc2, and Sc3 and the waveforms of V1 and V2 are shown in FIG. 6D. The conduction time ts1 of the switch Sc1 is consistent with the conduction time of the sampling switch Ss; the conduction interval of the switch Sc2 is complementary to the conduction interval of the switch Sc1; the conduction interval of the switch Sc3 starts from the rising edge of the switch Sc1 and continues for a short period of time; here, the conduction time ts3 of the switch Sc3 is shorter than the conduction time ts1 of the switch Sc1. Specifically, in order to avoid a DC offset between the voltage V2 and the voltage V1, when the switch Sc3 is turned on, an initial value of the voltage V2 is forcibly clamped to the voltage V1, so that the voltage V2 and the voltage V1 are synchronized once in each switching cycle. During the conduction interval of the switch Sc1, the adjustable current source I1 charges the holding capacitor Ch, causing the voltage V2 to rise, and the rising slope of V2 tracks the rising slope of V1. During the interval in which the switch Sc1 is off and the switch Sc2 is on, the adjustable current source I2 generates a falling slope of the voltage V2 according to a preset inductance value L and the output voltage Vo. Because there is an error between the preset inductance value and an actual inductance value, at time t1, a terminal value of the falling stage is not equal to a start value of the rising stage, resulting in an error in the current sensing result. In this implementation, the error detection unit E-det adjusts the magnitude of the preset inductance value, or adjusts the current magnitude of the adjustable current source I2 in the next switching cycle, according to the error between the end value of the falling stage and the start value of the rising stage at time t1, so as to gradually reduce the error in subsequent switching cycles, thereby further reducing the current sensing error.

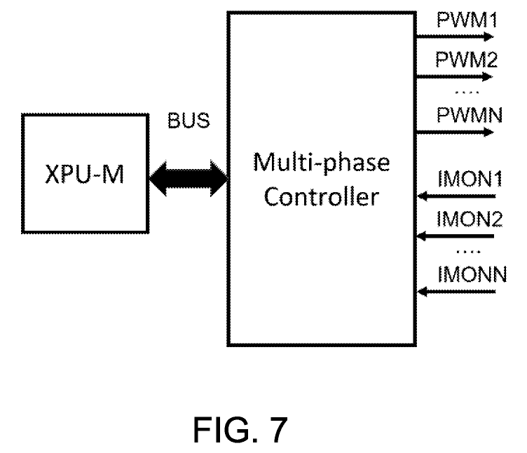

In addition, the present invention further shows a schematic diagram of the connection between multi-phase primary-side current sensing signals and a multi-phase controller in a parallel application of multi-phase transformer-based full-bridge power converters, as shown in FIG. 7. In the parallel application of multi-phase transformer-based full-bridge power converters, multiple current sensing units are included; the multiple current sensing units correspond one-to-one to detect current information of multiple full-bridge circuits, thereby outputting multiple current sensing signals IMON1, IMON2, ... , IMONn. The multiple current sensing signals IMON1, IMON2, ... , IMONn are used as current inputs to the multi-phase controller, together with other voltage feedback signals, to generate pulse-width control signals PWM1, PWM2, ... , PWMn for driving the multi-phase full-bridge power converters; wherein PWM1, PWM2, ... , PWMn are sequentially phase-shifted by 360 degrees/N. Here, the pulse-width control signal PWM1 includes at least two control signals PWM1A and PWM1B for driving the primary-side switches of the full-bridge circuit, with a phase shift of 180 degrees; similarly, among PWM2, ... , PWMn, PWM2 includes at least two control signals PWM2A and PWM2B for driving the primary-side switches of the full-bridge circuit, with a phase shift of 180 degrees; PWMn includes at least two control signals PWMnA and PWMnB for driving the primary-side switches of the full-bridge circuit, with a phase shift of 180 degrees. In the multi-phase controller for controlling the multi-phase full-bridge power converters, the multiple current sensing signals IMON1, IMON2, ... , IMONn may be used for current monitoring and reporting, for example, reporting between the communication bus BUS of the multi-phase controller and the XPU voltage management unit XPU-M; or the multiple current sensing signals IMON1, IMON2, ... , IMONn may be used to participate in control of the multi-phase full-bridge power converters, for example, participating in output voltage droop control, current sharing control, current protection, current-mode COT control, and the like required by the multi-phase full-bridge power converters; thereby further achieving reliable operation and high-performance output of the multi-phase full-bridge power converters.

In the present invention, the sampling resistor Rcs completes current sensing of the lower switches S2 and S4 of the primary-side full-bridge circuit. This function may also be replaced by current mirror circuits integrated in the lower switches S2 or S4; specifically, a current mirror integrated in the lower switch S2 detects the conduction current of S2, and a current mirror integrated in the lower switch S4 detects the conduction current of S4, and the two are superimposed according to phase.

The switching devices disclosed herein may be Si MOSFETs, SiC MOSFETs, GaN MOSFETs, IGBT devices, or the like, all of which can implement the switching functions disclosed in the present invention.

The " equal " or " same " or " equal to " disclosed by the application needs to consider the parameter distribution of engineering, and the error distribution is within +/-30%.

The embodiments in the specification are described in a progressive manner, each embodiment focuses on the difference from other embodiments, and the same similar parts between the embodiments can be referred to each other.

The above description of the disclosed embodiments enables a person skilled in the art to implement or use the present application. Various modifications to these embodiments will be readily apparent to those skilled in the art, and the generic principles defined herein may be implemented in other embodiments without departing from the spirit or scope of the application. Thus, the present application will not be limited to the embodiments shown herein but is to be accorded the widest scope consistent with the principles and novel features disclosed herein.

What is claimed is:

1. A primary-side current sensing unit applied to a transformer-based power converter, wherein the power converter comprises a primary-side circuit, a secondary-side circuit, an input positive terminal, an input negative terminal, an output positive terminal, and an output negative terminal;
wherein the primary-side circuit is connected across the input positive terminal and the input negative terminal, and the primary-side circuit comprises a primary-side switch;
wherein the secondary-side circuit is connected across the output positive terminal and the output negative terminal, and the secondary-side circuit comprises an inductor;
the primary-side current sensing unit comprising:
a current sampling unit connected between the primary-side circuit and the input negative terminal;
a sample-and-hold unit comprising a sampling switch and a filter unit, wherein an on-time of the sampling switch is less than or equal to an on-time of the primary-side circuit; and
a variable-gain amplification unit receiving an output voltage of the sample-and-hold unit and outputting a current sensing signal after amplifying the output voltage by a corresponding gain; wherein the gain of the variable-gain amplification unit is adjustable; wherein the output voltage of the sample-and-hold unit comprises current information during the on-time of the primary-side circuit.

2. The primary-side current sensing unit according to claim 1, further comprising a prediction unit; wherein the prediction unit receives the output voltage of the sample-and-hold unit, an output voltage of the prediction unit serves as an input of the variable-gain amplification unit, and the prediction unit is configured to predict current information during an off-time of the primary-side circuit.

3. The primary-side current sensing unit according to claim 2, wherein the prediction unit predicts the current information during the off-time of the primary-side circuit according to an output voltage of the secondary-side circuit and an inductance value, or predicts the current information according to a slope of a rising stage of the output voltage of the sample-and-hold unit and the output voltage of the secondary-side circuit.

4. The primary-side current sensing unit according to claim 2, wherein the output voltage of the sample-and-hold unit is superimposed with a DC component and then input to the prediction unit.

5. The primary-side current sensing unit according to claim 2, wherein the sample-and-hold unit adopts a hybrid DC and AC sensing mode.

6. The primary-side current sensing unit according to claim 2, wherein the prediction unit comprises an error detection unit; the error detection unit adjusts a slope of a falling stage of the current sensing signal according to an error signal of the current sensing signal; the error signal is a difference between a terminal value of the falling stage and an initial value of a rising stage in the current sensing signal.

7. The primary-side current sensing unit according to claim 6, wherein the prediction unit further comprises a power supply terminal, a ground terminal, a first adjustable current source, a second adjustable current source, a first switch, a second switch, a third switch, and a holding capacitor; an on-time of the first switch is consistent with an on-time of the sampling switch; an on-interval of the second switch is complementary to an on-interval of the first switch; and an on-time of the third switch is shorter than the on-time of the first switch.

8. The primary-side current sensing unit according to claim 7, wherein one end of the first switch is electrically connected to an output terminal of the first adjustable current source, and another end of the first switch is electrically connected to one end of the second switch, one end of the third switch and one end of the holding capacitor, and serves as an output terminal of the prediction unit; an input terminal of the first adjustable current source is electrically connected to the power supply terminal; another end of the third switch is electrically connected to the sample-and-hold unit; another end of the second switch is electrically connected to an input terminal of the second adjustable current source; an output terminal of the second adjustable current source and another end of the holding capacitor are both grounded; and another input terminal of the second adjustable current source is electrically connected to the error detection unit.

9. The primary-side current sensing unit according to claim 8, wherein when the third switch is turned on, the output voltage of the prediction unit is equal to the output voltage of the sample-and-hold unit.

10. The primary-side current sensing unit according to claim 1, wherein the sample-and-hold unit adopts a DC sensing mode.

11. The primary-side current sensing unit according to claim 10, wherein the sampling switch is turned on with a delay relative to turn-on of the primary-side switch.

12. The primary-side current sensing unit according to claim 1, wherein the filter unit comprises a filter resistor and a filter capacitor.

13. The primary-side current sensing unit according to claim 12, wherein the filter capacitor is a parasitic capacitor within the primary-side current sensing unit.

14. The primary-side current sensing unit according to claim 13, wherein the current sampling unit comprises a sampling resistor, and during a conduction period of the sampling switch, a voltage across the filter capacitor falls or rises following a voltage across the sampling resistor; a falling or rising slope of the voltage across the filter capacitor depends on a waveform of the voltage across the sampling resistor and a time constant of the filter resistor and the filter capacitor.

15. The primary-side current sensing unit according to claim 1, wherein the sampling switch is turned on during an interval in which the primary-side circuit is turned on, and an on-off frequency of the sampling switch is consistent with a frequency of a current waveform of the inductor.

16. The primary-side current sensing unit according to claim 1, wherein energy is transferred between the primary-side circuit and the secondary-side circuit through transformer coupling.

17. The primary-side current sensing unit according to claim 16, wherein the input negative terminal is short-circuited to the output negative terminal.

18. The primary-side current sensing unit according to claim 1, further comprising a controller, wherein the current sensing signal serves as an input signal of the controller, and together with other control signals, generates a pulse-width control signal.

19. The primary-side current sensing unit according to claim 18, wherein current monitoring and reporting are performed through the current sensing signal.

20. The primary-side current sensing unit according to claim 19, wherein the monitoring and reporting are performed between a communication bus of the controller and an XPU voltage management unit.

21. The primary-side current sensing unit according to claim 19, wherein the current sensing signal participates in droop control, current sharing control, current protection, or current-mode COT control required by the converter.

22. The primary-side current sensing unit according to claim 1, wherein the primary-side circuit is a full-bridge circuit, and the full-bridge circuit comprises two switch bridge arms electrically connected in parallel, each of the switch bridge arms comprises an upper switch and a lower switch electrically connected in series.

23. The primary-side current sensing unit according to claim 22, wherein the current sampling unit comprises a sampling resistor, and the sampling resistor is connected in series between sources of the two lower switches connected in parallel and the input negative terminal.

24. The primary-side current sensing unit according to claim 23, wherein the sampling switch is synchronously turned on or off with either one of the two primary-side lower switches.

25. The primary-side current sensing unit according to claim 22, wherein the current sampling unit comprises current mirror circuits integrated in the two primary-side lower switches, and the current sensing signal is a superposition of conduction currents of the two lower switches.
